(19) United States
(12) Patent Application Publication
(10) Pub. No.: US 2026/0082776 A1
(43) Pub. Date: Mar. 19, 2026

(54) METHOD FOR MANUFACTURING A DISPLAY DEVICE, AND SUBSTRATE BONDING APPARATUS USABLE FOR THE SAME

(71) Applicant: Samsung Display Co., Ltd., Yongin-si (KR)

(72) Inventors: Jong-Seok KIM, Yongin-si (KR); Byongho KANG, Yongin-si (KR); Ung-Soo LEE, Yongin-si (KR); Youngdo KIM, Yongin-si (KR); Yeonjae LEE, Yongin-si (KR); Jaihyuk CHOI, Yongin-si (KR)

(21) Appl. No.: 19/232,222

(22) Filed: Jun. 9, 2025

(30) Foreign Application Priority Data
Sep. 19, 2024 (KR) 10-2024-0126439

(51) Int. Cl. H10K 59/127; H10K 59/38; H10K 59/40; H10K 59/80; H10K 71/00

(52) U.S. Cl. CPC H10K 59/1275; H10K 59/38; H10K 59/40; H10K 59/873; H10K 71/851

(57) ABSTRACT

A method for manufacturing a display device including: preparing divided substrates, each of the divided substrates including a base substrate and a circuit layer; forming a light-emitting diode layer on the circuit layer for each of the divided substrates; forming an encapsulation layer on the light-emitting diode layer for each of the divided substrates; aligning the divided substrates having the encapsulation layer formed therein such that a gap is formed between adjacent ones of the divided substrates; after the aligning of the divided substrates, bonding the divided substrates to form a single bonded substrate; and forming a functional layer on the encapsulation layer for the bonded substrate.

### CROSS-REFERENCE TO RELATED APPLICATION

The present application claims priority to and the benefit of Korean Patent Application No. 10-2024-0126439, filed on Sep. 19, 2024, in the Korean Intellectual Property Office, the entire disclosure of which is incorporated herein by reference.

### BACKGROUND

### 1. Field

Aspects of embodiments of the present disclosure relate to a method for manufacturing a display device and a substrate bonding apparatus usable for such a method.

### 2. Description of the Related Art

Electronic devices that provide images to users, such as smartphones, digital cameras, laptop computers, navigation systems, and smart televisions, include a display device for displaying such images. The display device generates images and presents the generated images to users through a display screen.

Various types of display panels, including liquid crystal display panels and organic light-emitting display panels, have been developed for use in display devices. From among these types of display panels, the organic light-emitting display panel features a structure in which a base substrate, a circuit layer, a light-emitting diode layer, and an encapsulation layer are sequentially stacked.

Accordingly, a method for manufacturing a display device generally includes a backplane (BP) process for forming the circuit layer, an evaporation (EV) process for forming the light-emitting diode layer, and an encapsulation (EN) process for forming the encapsulation layer.

A touch panel and/or a polarizing film may be affixed to the encapsulation layer by way of an adhesive layer. Recently, instead of the method using the adhesive layer, a subsequent on-cell process has been developed in which a touch-sensing layer and/or a color filter layer are/is directly formed on the encapsulation layer.

### SUMMARY

An embodiment of the present disclosure provides a method for manufacturing a display device that enhances productivity and includes a subsequent on-cell process in which a functional layer, such as a touch-sensing layer or a color filter layer, is directly formed on an encapsulation layer, as well as a substrate bonding apparatus that is usable for such a method.

A method for manufacturing a display device, according to an embodiment of the present disclosure, includes a divided substrate preparation step, a deposition step, an encapsulation step, an alignment step, a bonding step, and a functional layer formation step.

In the divided substrate preparation step, divided substrates may be prepared, and each of the divided substrates may include a base substrate and a circuit layer. In the deposition step, a light-emitting diode layer may be formed on the circuit layer, and the deposition step may be performed for each of the divided substrates. In the encapsulation step, an encapsulation layer may be formed on the light-emitting diode layer, and the encapsulation step may be performed for each of the divided substrates. After the encapsulation step, in the alignment step, the divided substrates may be aligned so that a gap is formed between adjacent ones of the divided substrates. After the alignment step, in the bonding step, the divided substrates may be bonded to form a single bonded substrate. In the functional layer formation step, a functional layer may be formed on the encapsulation layer, and the functional layer formation step may be performed for the bonded substrate.

According to one embodiment of the present disclosure, the method for manufacturing a display device may further include, prior to the divided substrate preparation step, a mother substrate preparation step, a circuit layer formation step, and a division step. In the mother substrate preparation step, a mother substrate, including the base substrate, may be prepared. In the circuit layer formation step, the circuit layer may be formed on the base substrate, and the circuit layer formation step may be performed for the mother substrate. In the division step, the mother substrate, having undergone the circuit layer formation step, may be cut to form the divided substrates.

According to one embodiment of the present disclosure, the bonded substrate may have the same dimensions as the mother substrate in a planar view. According to one embodiment of the present disclosure, in the bonding step, the divided substrates may be bonded by using an adhesive tape. According to one embodiment of the present disclosure, in the bonding step, an adhesive layer may be formed in the gap to bond the divided substrates. According to one embodiment of the present disclosure, in the bonding step and after forming the adhesive layer, adjacent divided substrates from among the divided substrates may be connected with the adhesive tape. According to one embodiment of the present disclosure, the adhesive tape may extend along a lengthwise direction of the gap and may be attached to upper edges of the adjacent divided substrates in a width direction across the gap. According to one embodiment of the present disclosure, the adhesive tape may be an ultraviolet-release tape that exhibits decreased adhesive force when irradiated by ultraviolet rays.

According to one embodiment of the present disclosure, the functional layer may include a touch-sensing layer formed directly on the encapsulation layer. According to one embodiment of the present disclosure, the functional layer may include a color filter layer formed directly on the encapsulation layer. According to one embodiment of the present disclosure, the method for manufacturing a display device may further include a redivision step. In the redivision step, redivided substrates may be formed by removing (e.g., cutting) a bonded portion from the bonded substrate that has undergone the functional layer formation step. According to one embodiment of the present disclosure, the method for manufacturing a display device may further include a cell process. Each of the redivided substrates may have cell regions and a peripheral region defined therein, and in the cell process, the redivided substrates may be cut to separate the cell regions.

A substrate bonding apparatus, according to another embodiment of the present disclosure, may include a shuttle, stages, stage driving units, an adhesive dispensing unit, and a transport unit. The stages may be arranged on the shuttle, and each of the stages may have an upper surface on which a divided substrate is mounted. The stage driving units may be coupled to the shuttle and may be configured to transport and rotate each of the stages. The transport unit may be configured to move the shuttle or the adhesive dispensing unit, which is configured to fill an adhesive in a gap between adjacent ones of the divided substrates.

According to one embodiment of the present disclosure, the adhesive dispensing unit may include an adhesive dispensing nozzle and a UV irradiation unit configured to irradiate UV light onto the adhesive in the gap. According to one embodiment of the present disclosure, the adhesive dispensing unit may further include an inspection unit configured to examine the condition of the adhesive layer formed in the gap.

According to one embodiment of the present disclosure, the substrate bonding apparatus may further include an image capturing unit and a control unit. The image capturing unit may be configured to generate captured images of the divided substrates mounted on the stages. The control unit may be configured to control the stage driving units based on the captured images such that the gap has a constant size between the divided substrates.

According to one embodiment of the present disclosure, the substrate bonding apparatus may further include a supporter. The supporter may be arranged between the stages to support lower edges of the divided substrates and cover the gap in a planar view.

According to one embodiment of the present disclosure, the supporter may include a strip, an unwinder, and a winder. The strip may support the lower edges of the divided substrates and covers the gap in a planar view. The unwinder may be configured to draw out the strip, and the winder may be configured to wind the strip.

According to one embodiment of the present disclosure, the substrate bonding apparatus may further include a supporter lifting unit. The supporter lifting unit may be configured to transport the supporter to a first position where the supporter supports the lower edges of the divided substrates and to a second position being lower than the first position.

According to one embodiment of the present disclosure, the substrate bonding apparatus may further include a first transport hand and a second transport hand. The first transport hand may be configured to load the divided substrates onto the stages, respectively. The second transport hand may be configured to unload a bonded substrate, which is formed by bonding the divided substrates together, from the stages. Each of the stages may have grooves in the upper surface thereof to allow the first transport hand and the second transport hand to enter and exit in a direction parallel to the upper surface.

The method for manufacturing a display device according to one embodiment of the present disclosure may include an on-cell process of forming a functional layer on the encapsulation layer.

Moreover, with the method for manufacturing a display device according to one embodiment of the present disclosure, productivity can be improved by carrying out the subsequent process on the bonded substrate formed by having the divided substrates bonded together, rather than on each of the divided substrate individually.

### BRIEF DESCRIPTION OF THE DRAWINGS

These and/or other aspects and features of the present disclosure will become apparent and more readily appreciated from the following description of embodiments, taken in conjunction with the accompanying drawings, in which:

FIG. 1 is a perspective view of a display device according to an embodiment of the present disclosure;

FIG. 2 is a schematic cross-sectional view of the display device taken along the line A-A in FIG. 1;

FIG. 3 is a flowchart describing a method for manufacturing a display device according to an embodiment of the present disclosure;

FIGS. 4 through 16 illustrate steps of the method for manufacturing a display device described in FIG. 3;

FIG. 17 illustrates a modified embodiment of the bonding process shown in FIG. 12;

FIG. 18 illustrates a modified embodiment of the bonding process shown in FIG. 12;

FIG. 19 illustrates a modified embodiment of the bonding process shown in FIG. 12;

FIG. 20 illustrates a modified embodiment of the bonding process shown in FIG. 12;

FIGS. 21 and 22 show a substrate bonding apparatus according to an embodiment of the present disclosure;

FIG. 23 illustrates a substrate loading operation of the substrate bonding apparatus shown in FIG. 21;

FIG. 24 illustrates a substrate bonding operation of the substrate bonding apparatus shown in FIG. 21;

FIG. 25 illustrates a substrate unloading operation of the substrate bonding apparatus shown in FIG. 21;

FIG. 26 is a cross-sectional view taken along the line I-I in FIG. 25.

### DETAILED DESCRIPTION

References will now be made, in detail, to embodiments, examples of which are illustrated in the accompanying drawings. The embodiments may have a variety of forms and permutations, and the present disclosure shall by no means be construed as being limited to the described embodiments. Rather, the present disclosure shall be construed to encompass all forms, permutations, equivalents, and substitutes covered by the technical ideas and scope of the present disclosure. Accordingly, embodiments of the present disclosure are merely described below, by referring to the figures, to explain aspects and features of the present disclosure.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The control unit and/or any other relevant devices or components according to embodiments of the present disclosure described herein may be implemented utilizing any suitable hardware, firmware (e.g., an application-specific integrated circuit), software, and/or a suitable combination of software, firmware, and hardware. For example, the various components of the control unit may be formed on one integrated circuit (IC) chip or on separate IC chips. Further, the various components of the control unit may be implemented on a flexible printed circuit film, a tape carrier package (TCP), a printed circuit board (PCB), or formed on a same substrate as the control unit. Further, the various components of the control unit may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device or the functionality of a particular computing device may be distributed across one or more other computing devices without departing from the scope of the exemplary embodiments of the present disclosure.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

In one embodiment of the present disclosure, directions labeled as first through third directions DR1-DR3 may be defined. The first direction DR1 may be parallel to one side of a display device DD. The second direction DR2 may intersect the first direction DR1 and may be parallel to another side of the display device DD. The third direction DR3 may be perpendicular to one surface of the display device DD. In an embodiment of the present disclosure, the phrase “in a planar view” or “in a plan view” refers to viewing along the third direction DR3.

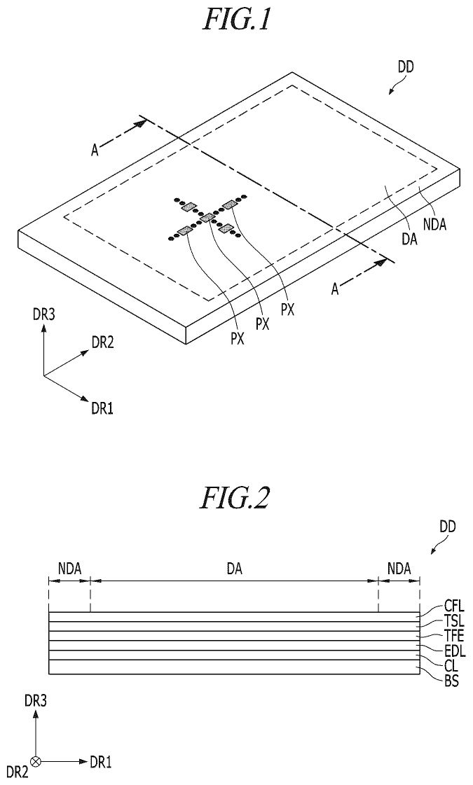

FIG. 1 is a perspective view of a display device according to an embodiment of the present disclosure. Referring to FIG. 1, the display device DD, according to an embodiment of the present disclosure, is an image display device, which may be used in (e.g., may be incorporated in) a variety of products, including portable electronic devices, such as mobile phones, smartphones, tablet personal computers, smart watches, watch phones, mobile communication terminals, electronic notebooks, e-books, portable multimedia players (PMPs), navigation devices, and ultra-mobile PCs (UMPCs). Additionally, the display device DD may be used in televisions, laptop computers, monitors, digital billboards, and devices associated with the Internet of Things (IoT).

The display device DD may be one of an organic light-emitting display device, a liquid crystal display device, a plasma display device, a field emission display device, an electrophoretic display device, an electrowetting display device, a quantum dot light-emitting display device, and a micro-LED display device. Hereinafter, the display device DD will be described as an organic light-emitting display device as an example, but it shall be appreciated that the present disclosure is not limited to the display device DD being an organic light-emitting display device.

The display device DD may have a display area DA and a non-display area NDA defined therein. The display area DA is an area at where images are displayed, and the non-display area NDA is an area that is positioned around the periphery of the display area DA and does not display images. In some embodiments, the non-display area NDA may be omitted.

In the present embodiment, the display area DA is shown as having a rectangular shape, and the non-display area NDA is illustrated as surrounding (e.g., extending around a periphery of) the display area DA. However, the shapes of the display area DA and the non-display area NDA are not limited to these configurations and may be designed in various forms.

The display area DA may have pixels PX for implementing (e.g., forming and/or displaying) images arranged therein. Each of the pixels PX may include a light-emitting diode and a pixel circuit configured to control the operation of the light-emitting diode. The light-emitting diode may include, but is not limited to, an organic light-emitting diode, and the pixel circuit may include, but is not limited to, a thin-film transistor.

The pixels PX may be arranged in a pattern (e.g., a predetermined pattern) and may be repeatedly arranged within the display area DA. For example, the pixels PX may be arranged in a Pentile® (a registered trademark of Samsung Display Co., Ltd.) arrangement pattern, a stripe arrangement pattern, or a Diamond Pixel® (a registered trademark of Samsung Display Co., Ltd.) arrangement pattern, etc.

The non-display area NDA may have signal lines, which are connected to the pixels PX, arranged therein. The signal lines may include a data line connected to a source electrode of a thin-film transistor to provide a data signal, a gate line connected to a gate electrode of the thin-film transistor to provide a gate signal, and a power line connected to the light-emitting diode to supply voltage.

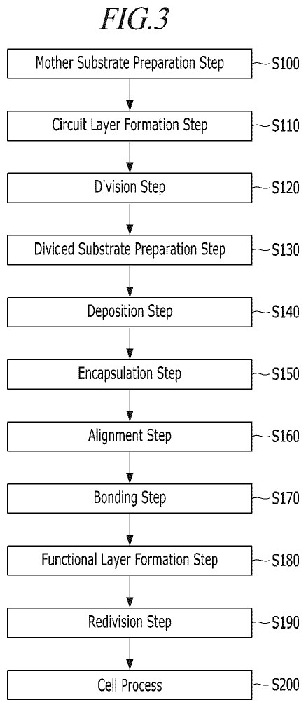

FIG. 2 is a schematic cross-sectional view of the display device shown in FIG. 1, taken along the line A-A in FIG. 1. Referring to FIG. 2, the display device DD may include a base substrate BS, a circuit layer CL, a light-emitting diode layer EDL, an encapsulation layer TFE, a touch-sensing layer TSL, and a color filter layer CFL.

The base substrate BS may be a member that provides (or forms) a base surface on which the circuit layer CL is disposed. The base substrate BS may be made of suitable materials, such as glass, ceramic, metal, or a polymer resin, such as polyimide. However, the base substrate BS is not limited to these materials and may include inorganic, organic, and/or composite material layers and may be configured as a single layer or multiple layers.

The circuit layer CL may be arranged on the base substrate BS and may include a pixel circuit and signal lines. The pixel circuit may include pixel transistors for driving the light-emitting diodes. Moreover, the circuit layer CL may include peripheral transistors arranged in the non-display area NDA and configured to output signals for controlling the pixel transistors within the pixel circuit.

The light-emitting diode layer EDL may be arranged on the circuit layer CL and may include light-emitting diodes and a pixel defining layer. Each of the light-emitting diodes may include a first electrode, a hole functional layer, a light-emitting layer, an electron functional layer, and a second electrode. The pixel defining layer may be positioned on the circuit layer CL and may be arranged to cover a region between first electrodes in a planar view. The pixel defining layer may be arranged to correspond to a non-light-emitting area, and light-emitting areas may be defined by the pixel defining layer.

The encapsulation layer TFE may be positioned on the light-emitting diode layer EDL and may be configured to protect the light-emitting diodes of the light-emitting diode layer EDL from moisture, oxygen, and/or foreign substances. The encapsulation layer TFE may include a glass substrate or a synthetic resin substrate. However, the encapsulation layer TFE is not limited to these materials and may be a stacked structure composed of an inorganic layer, an organic layer, and an inorganic layer.

The touch-sensing layer TSL may be positioned on the encapsulation layer TFE and may be configured to detect external inputs, such as a touch made by a user's finger or stylus pen, to enable the display device DD to acquire coordinate information corresponding to the touch position. The touch-sensing layer TSL may be formed directly on the encapsulation layer TFE rather than being attached to the encapsulation layer TFE by way of an adhesive layer.

The touch-sensing layer TSL may include connection electrodes, a touch insulating layer, touch electrodes, and a protective layer. The connection electrodes may be arranged on the encapsulation layer TFE and may function to connect drive electrodes or sensing electrodes from among the touch electrodes. The touch electrodes may be arranged on the connection electrodes and may act as the drive electrodes or the sensing electrodes. The connection electrodes and the touch electrodes may have a mesh structure to allow light emitted from the light-emitting diodes to pass therethrough.

The connection electrodes and the touch electrodes may be positioned in the non-light-emitting area to avoid overlapping with the light-emitting areas. The connection electrodes and the touch electrodes may include a metal layer or a transparent conductive layer. The touch insulating layer may be arranged between the connection electrodes and the touch electrodes and may be provided with touch contact holes for electrically connecting the connection electrodes and the touch electrodes. The protective layer may be positioned on the touch electrodes and the touch insulating layer and may cover the touch electrodes and the touch insulating layer. The protective layer may provide a flat base surface for forming the color filter layer CFL.

The color filter layer CFL may be formed directly on the touch-sensing layer TSL rather than by being attached to the touch-sensing layer TSL by way of an adhesive layer. The color filter layer CFL may include color filters, a light-blocking layer, and a barrier layer. The color filters may include, but are not limited to, a red filter configured for transmitting (or configured to transmit) red light, a green filter configured for transmitting green light, and a blue filter configured for transmitting blue light.

The light-blocking layer may be a black matrix and may include organic or inorganic light-blocking materials. The light-blocking layer may be configured to prevent light leakage and may demarcate boundaries between adjacent color filters. The color filters may be arranged to correspond to light-emitting areas, respectively, and the light-blocking layer may be arranged corresponding to the non-light-emitting area.

The barrier layer may be arranged above or below the color filter layer CFL and may block moisture and/or oxygen from permeating therethrough. In some embodiments, the barrier layer may be omitted.

In the present specification, when a first layer is described as being “directly formed” on a second layer, it refers to forming components of the first layer sequentially on the second layer by use of, for example, a deposition process, a patterning process, etc., rather than by fabricating the first layer in the form of a film or panel and then attaching the prefabricated first layer on the second layer by way of an adhesive layer.

For example, at least one of the connection electrodes, the touch insulating layer, the touch electrodes, and the protective layer of the touch-sensing layer TSL may be formed on the encapsulation layer TFE by a deposition process, a patterning process, etc. Similarly, at least one of the color filters, the light-blocking layer, and the barrier layer of the color filter layer CFL may be formed on the touch-sensing layer TSL by a deposition process, a patterning process, etc.

Additionally, in the present embodiment, although the display device DD is described as including both the touch-sensing layer TSL and the color filter layer CFL directly formed on the encapsulation layer TFE, the present disclosure is not limited thereto, and either the touch-sensing layer TSL or the color filter layer CFL may be omitted. For example, if the touch-sensing layer TSL is substituted with a touch panel affixed with an adhesive layer, the color filter layer CFL may be formed directly on the encapsulation layer TFE.

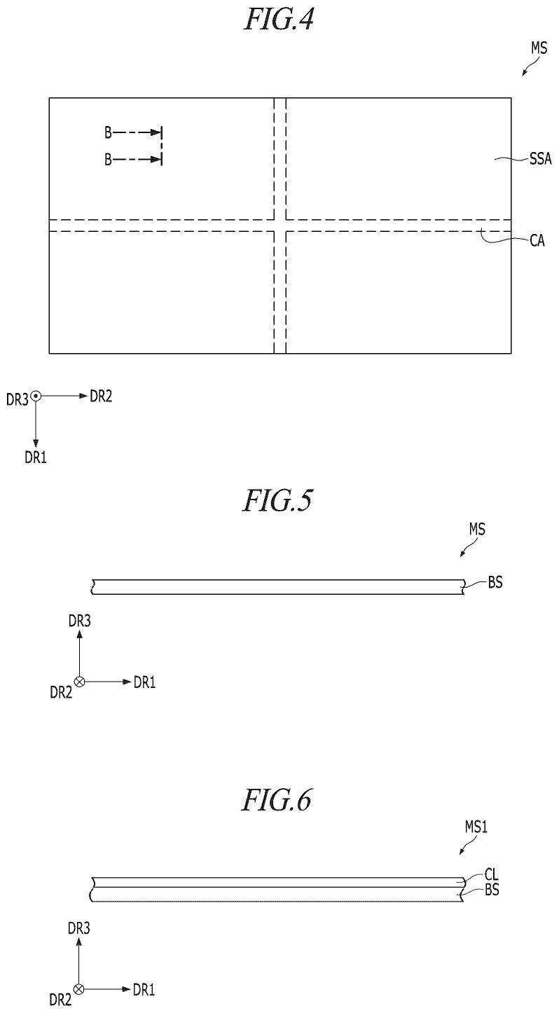

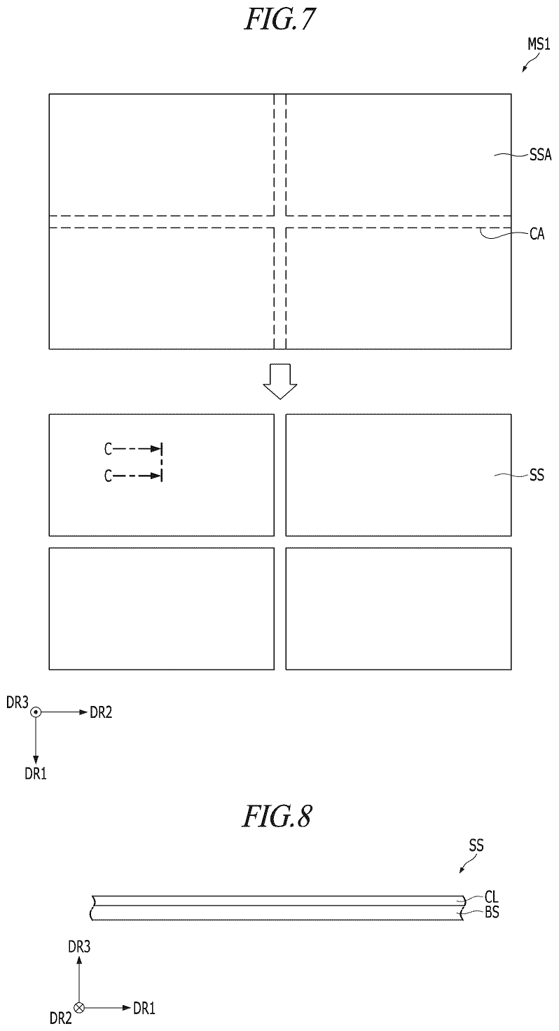

FIG. 3 is a flowchart describing a method for manufacturing a display device according to an embodiment of the present disclosure, and FIGS. 4 through 16 illustrate steps of the method for manufacturing a display device described with reference to FIG. 3.

Referring to FIG. 3, the method for manufacturing a display device according to an embodiment of the present disclosure may include a mother substrate preparation step (S100), a circuit layer formation step (S110), a division step (S120), a divided substrate preparation step (S130), a deposition step (S140), an encapsulation step (S150), an alignment step (S160), a bonding step (S170), a functional layer formation step (S180), a redivision step (S190), and a cell process (S200).

Hereinafter, each of the above described steps of the method for manufacturing a display device DD will be further described with reference to FIGS. 4 through 16. The above description relating to the components of the display device DD may equally apply to the components, designated with the same reference numerals/symbols, formed through this manufacturing method.

FIG. 4 is a perspective view of a mother substrate, and FIG. 5 is a cross-sectional view of the mother substrate shown in FIG. 4, taken along the line B-B in FIG. 4. Referring to FIGS. 4 and 5, in the mother substrate preparation step (S100), a mother substrate MS may be prepared. The mother substrate MS may be defined with divided substrate areas SSA and a cutting area CA positioned between the divided substrate areas SSA. Although the embodiment illustrated in FIG. 4 includes four divided substrate areas SSA in the mother substrate MS, the number of divided substrate areas SSA is not limited thereto. The mother substrate MS may include (or may be) a base substrate BS.

Referring to FIG. 6, in the circuit layer formation step (S110), the circuit layer CL may be formed on the base substrate BS for the mother substrate MS. As a result, the mother substrate MS1, which has undergone the circuit layer formation step (S110), includes the base substrate BS and the circuit layer CL.

FIG. 7 shows the mother substrate before and after the division process, and FIG. 8 is a cross-sectional view of a divided substrate shown in FIG. 7, taken along the line C-C in FIG. 7. Referring to FIGS. 7 and 8, in the division step (S120), the mother substrate MS1, which has undergone the circuit layer formation step (S110), may be cut to form divided substrates SS. As a result, each of the divided substrates SS prepared in the divided substrate preparation step (S130) may include the base substrate BS and the circuit layer CL. The divided substrates SS may correspond to the divided substrate areas SSA of the mother substrate MS1. The cutting area CA of the mother substrate MS1 may be an area removed in the cutting process. For example, the mother substrate MS1 may be cut by using laser equipment.

Referring to FIG. 9, in the deposition step (S140), a light-emitting diode layer EDL may be formed on the circuit layer CL, and the deposition step (S140) may be performed for each of the divided substrate SS. As a result, each of the divided substrate SS1 that has undergone the deposition step (S140) includes the base substrate BS, the circuit layer CL, and the light-emitting diode layer EDL. The divided substrates SS may be individually fed into a first process facility that performs the deposition step (S140). For example, once one of the divided substrates SS is fed into the first process facility and discharged after the deposition process is completed, another one of the divided substrates SS may be fed into the first process facility.

Referring to FIG. 10, in the encapsulation step (S150), an encapsulation layer TFE may be formed on the light-emitting diode layer EDL, and the encapsulation step (S150) may be performed for each of the divided substrate SS1 that has undergone the deposition step (S140). As a result, each of the divided substrates SS2 that has undergone the encapsulation step (S150) includes the base substrate BS, the circuit layer CL, the light-emitting diode layer EDL, and the encapsulation layer TFE. The divided substrates SS1 may be individually fed into a second process facility that performs the encapsulation step (S150). For example, once one of the divided substrates SS1 is fed into the second process facility and discharged after the encapsulation process is completed, another one of the divided substrates SS1 may be fed into the second process facility.

FIG. 11 shows the divided substrates before and after the alignment process. Referring to FIG. 11, in the alignment step (S160), the divided substrates SS2, which have undergone the encapsulation step (S150), may be aligned to provide a gap G (e.g., a constant or predetermined gap) between the divided substrates SS2. For instance, the divided substrates SS2 may be primarily aligned by controlling a first transport hand configured for loading the divided substrates SS2 onto respective stages and may be secondarily aligned by controlling stage driving units configured for transporting and rotating the respective stages.

FIG. 12 shows an example of the bonding process for the divided substrates, and FIG. 13 is a cross-sectional view of the bonded substrate shown in FIG. 12, taken along the line D-D in FIG. 12. Referring to FIGS. 11 through 13, in the bonding step (S170), the divided substrates SS2 that have undergone the alignment step (S160) may be bonded to form a single bonded substrate JS. For example, the divided substrates SS2 may be bonded by way of an adhesive layer AL formed in the gap G. The adhesive layer AL may be formed by filling the gap G with an adhesive and curing the adhesive by irradiating ultraviolet light. The bonded substrate JS may have substantially the same size and shape as the mother substrate MS in a planar view. To this end, in the alignment step (S160), the gap G may be formed to be substantially the same size and shape as the cutting area CA. As a result, the transport hand used for transporting the mother substrate MS may also be used to unload the bonded substrate JS from the stages described above.

Referring to FIG. 14, in the functional layer formation step (S180), a functional layer may be directly formed on the encapsulation layer TFE of the bonded substrate JS. The functional layer may include, but is not limited to, a touch-sensing layer TSL and/or a color filter layer CFL. As a result, the bonded substrate JS1 that has undergone the functional layer formation step (S180) includes the base substrate BS, the circuit layer CL, the light-emitting diode layer EDL, the encapsulation layer TFE, the touch-sensing layer TSL, and the color filter layer CFL. The bonded substrate JS may be fed into a third process facility that performs the functional layer formation step (S180). As a result, productivity may be increased by approximately four times compared to feeding each of the divided substrates SS sequentially into the third process facility.

FIG. 15 shows the bonded substrate before and after the redivision step. Referring to FIG. 15, in the redivision step (S190), the adhesive layer AL may be removed or cut from the bonded substrate JS1, which has undergone the functional layer formation step (S180), to form redivided substrates SS′. As a result, each of the redivided substrate SS′ includes the base substrate BS, the circuit layer CL, the light-emitting diode layer EDL, the encapsulation layer TFE, the touch-sensing layer TSL, and the color filter layer CFL. Moreover, the redivided substrates SS′ may include the divided substrates SS3, respectively. The adhesive layer AL may be cut by using laser equipment or a wheel cutter. However, the present disclosure is not limited to what is described herein, and the bonded substrate JS1 may also be divided by forming a crack in the adhesive layer AL and pulling apart (e.g., separating) the divided substrates SS3. In such embodiments, each of the redivided substrates SS′ may include part of (e.g., a residual part of) the adhesive layer AL along with each of the divided substrates SS3.

FIG. 16 shows the redivided substrates before and after the cell process. Referring to FIG. 16, each of the redivided substrate SS′ may be defined with cell areas C and a peripheral area PA surrounding (e.g., extending around the periphery of) the cell areas C, and in the cell process (S200), each of the redivided substrates SS′ may be cut along the boundaries of the cell areas C. As a result, a display device DD as shown in FIGS. 1 and 2 may be obtained from each of the cell areas C.

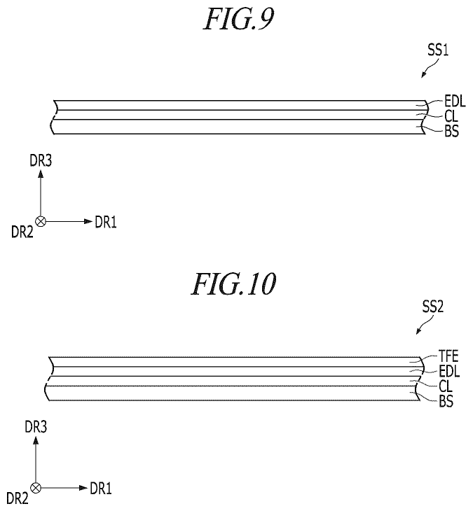

FIG. 17 illustrates another embodiment of the bonding process shown in FIG. 12. Referring to FIG. 17, the divided substrates SS2 may be joined by way of an adhesive tape T in addition to the adhesive layer AL. The adhesive layer AL maintains the separation distance between the divided substrates SS2, thereby preventing damage from collision between the divided substrates SS2 in subsequent processes and improves resistance to moisture penetration. The adhesive tape T may be further configured to enhance bonding strength.

The adhesive tape T may extend along the gap G in the lengthwise direction and may be attached to the upper edge of adjacent divided substrates SS2 across the gap G in the widthwise direction. The adhesive tape T may be attached by using a roll laminator. The adhesive tape T may be an ultraviolet-release tape, which exhibits reduced adhesion strength upon exposure to ultraviolet rays. Therefore, in the redivision step (S190), the adhesive tape T may be readily removed by irradiation of ultraviolet rays.

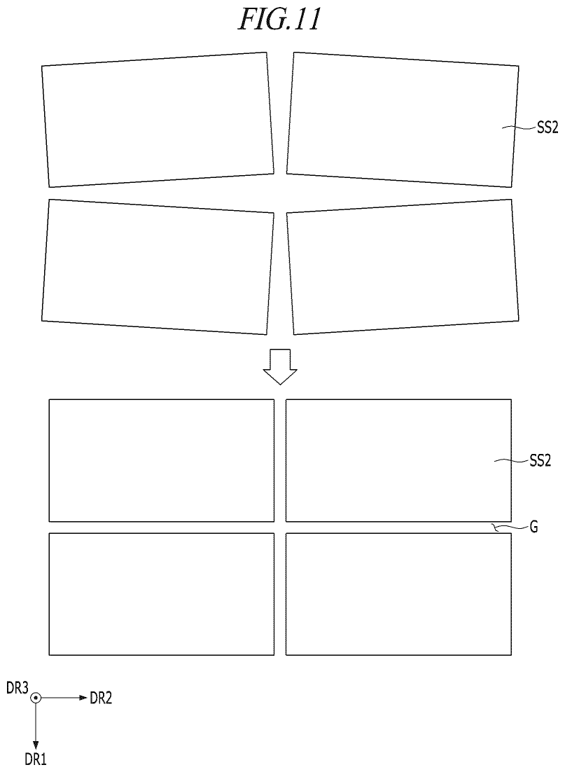

FIG. 18 illustrates another embodiment of the bonding process shown in FIG. 12. Referring to FIG. 18, in the bonding step (S170), the divided substrates SS2 may be bonded by using the adhesive tape T, and the adhesive layer AL may be omitted.

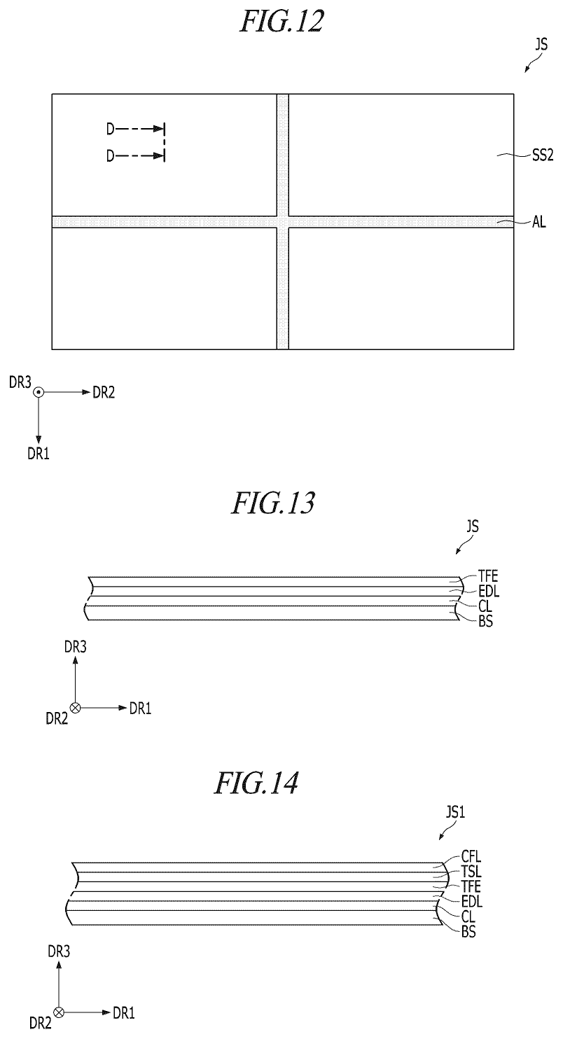

FIG. 19 illustrates another embodiment of the bonding process shown in FIG. 12. Referring to FIG. 19, in the bonding step (S170), the bonded substrate JS4 may be formed from only a portion of the divided substrates SS2 rather than from all of the divided substrates SS2, and the divided substrates SS2 that are bonded with each other may be arranged in such a way that the long edges of the divided substrates SS2 face each other. For instance, if four divided substrates SS are obtained from the mother substrate MS1, two of the divided substrates SS2 may form the bonded substrate JS4.

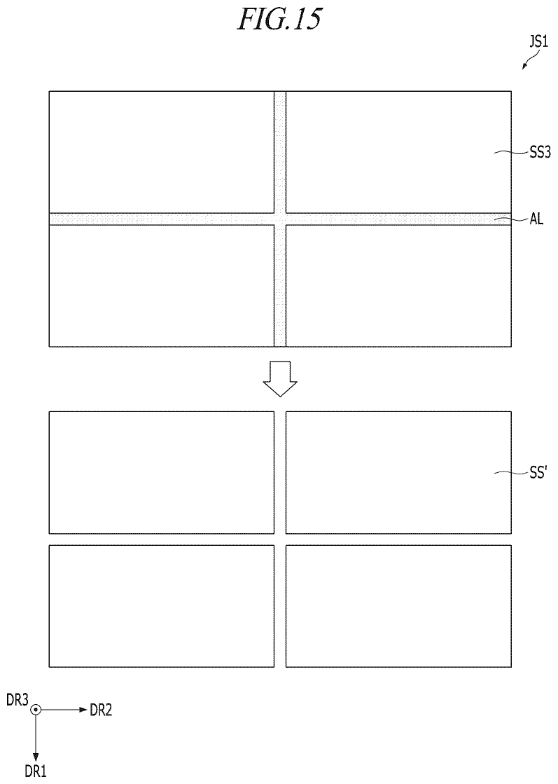

FIG. 20 illustrates another embodiment of the bonding process shown in FIG. 12. Referring to FIG. 20, in the bonding step (S170), the bonded substrate JS5 may be formed from only a portion of the divided substrates SS2 rather than from all of the divided substrates SS2, and the divided substrates SS2 that are bonded with each other may be arranged in such a way that the short edges of the divided substrates SS2 face each other. For example, if four divided substrates SS are obtained from the mother substrate MS1, two of the divided substrates SS2 may form the bonded substrate JS5.

According to embodiments of the present embodiment, the steps of the method for manufacturing the display device may be carried out in an order different from the one described above as long as there is no inconsistency with the aforementioned description.

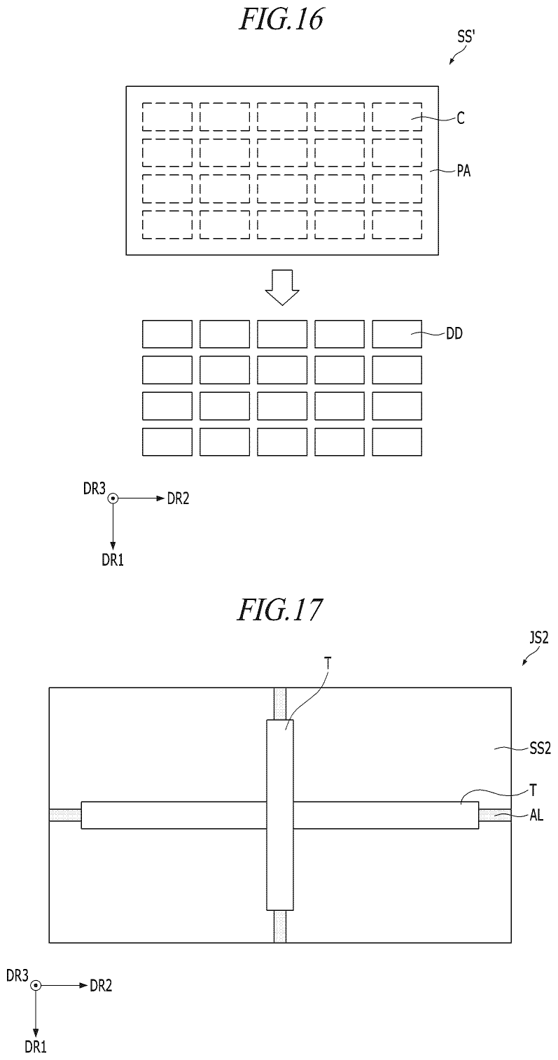

FIGS. 21 and 22 illustrate a substrate bonding apparatus 10 according to an embodiment of the present disclosure. The substrate bonding apparatus 10, according to an embodiment of the present disclosure, may be used in the bonding step S170, as described with reference to FIG. 12. However, the use of the substrate bonding apparatus 10 is not necessarily limited to this step.

In the present embodiment, the first through third directions DR1-DR3 may be defined as described above or as follows. The first direction DR1 may be parallel to an upper surface 201 of a stage 200. The second direction DR2 may cross (e.g., intersect) the first direction DR1 and may be parallel to the upper surface 201 of the stage 200. The third direction DR3 may be perpendicular to the upper surface 201 of the stage 200.

Referring to FIGS. 21 and 22, the substrate bonding apparatus 10 may include a shuttle 100, stages 200, stage driving units 210, an adhesive dispensing unit 400, and a transport unit 500 and may further include a supporter 300, a supporter lifting unit 310, an image capturing unit 600, and/or a control unit 700.

The shuttle 100 may be positioned on a platform F, and the stages 200 may be arranged on the shuttle 100. The stages 200 may be mounted, respectively, with divided substrates SS2, which are to be bonded. For example, the number of the stages 200 may be equal to the number of the divided substrates SS2. The mounting, that is, the loading, of each of the divided substrates SS2 may be performed by a first transport hand TH1.

The stage driving units 210 may each be coupled to the shuttle 100 and may be configured to transport and rotate each of the stages 200. For instance, one stage driving unit 210 may transport one stage 200 in the first direction DR1 and the second direction DR2 and may rotate the one stage 200 about an axis aligned with the third direction DR3. One stage 200 and one stage driving unit 210 driving the one stage 200 may constitute one UVW stage, which is well-known in the technical field to which the present disclosure pertains.

The supporter 300 may be positioned between the stages 200 and may be configured to support the lower edges of the divided substrates SS2 loaded on the stages 200 and cover the gap G (see, e.g., FIG. 11) between the divided substrates SS2 in a planar view. As a result, adhesive may be filled in a stable fashion within the gap G between the divided substrates SS2, and the adhesive may not spread onto the lower surfaces of the divided substrates SS2.

The supporter lifting unit 310 may raise and lower the supporter 300 in the third direction DR3. As a result, interference between the supporter 300 and the second transport hand TH2, which is configured to unload the bonded substrate JS formed by bonding the divided substrates SS2 from the stages 200, may be avoided. Moreover, once the adhesive filled in the gap G between the divided substrates SS2 has cured to form the adhesive layer AL, the supporter 300 can be separated from the adhesive layer AL.

The adhesive dispensing unit 400 may include an adhesive dispensing nozzle 410, which may be configured to dispense adhesive for bonding the divided substrates SS2. The adhesive dispensing unit 400 may further include an ultraviolet irradiation unit 420, which may be configured to irradiate ultraviolet rays onto the adhesive dispensed from the adhesive dispensing nozzle 410 to cure the adhesive.

The adhesive dispensing unit 400 may further include an inspection unit 430. The inspection unit 430 may be configured to inspect the condition of the adhesive layer AL formed by curing the adhesive dispensed from the adhesive dispensing nozzle 410 and filled in the gap G between the divided substrates SS2. For example, the inspection unit 430 may be configured to generate captured images of the adhesive layer AL and may analyze the captured images to inspect the condition of the adhesive layer AL, for example, to determine whether or not there are any defects. A defect in the adhesive layer AL may include the adhesive layer AL protruding above the upper surfaces of the divided substrates SS2.

The transport unit 500 may be configured to transport the shuttle 100 or the adhesive dispensing unit 400 on the platform F so that adhesive may fill the gap G provided between the divided substrates SS2 loaded on the stages 200. For example, the transport unit 500 may be configured to move the shuttle 100 in the second direction DR2 and the adhesive dispensing unit 400 in the first direction DR1. The adhesive dispensing unit 400 may be moved by a gantry-style transport device.

The image capturing unit 600 may be configured to generate captured images of the divided substrates SS2 loaded on the stages 200. For example, the image capturing unit 600 may be positioned above each of the stages 200 and may include cameras for capturing alignment marks provided on each of the divided substrates SS2.

The control unit 700 may be configured to control the stage driving units 210 based on the captured images generated by the image capturing unit 600 such that the gap G (e.g., a gap having a designed or predetermined size) is formed between the divided substrates SS2. The control unit 700 may be configured to control the supporter lifting unit 310, the adhesive dispensing unit 400, the transport unit 500, the image capturing unit 600, the first transport hand TH1, and/or the second transport hand TH2 to operate according to a pre-set program.

Hereinafter, the operation of the substrate bonding apparatus 10 is briefly described.

First, the first transport hand TH1 may load each of the divided substrate SS2 onto each of the stages 200. Then, each of the stage driving units 210 may transport and rotate each of the stages 200 to form gap G between the divided substrates SS2. For example, the divided substrates SS2 may be aligned such that the gap G is formed between the divided substrates SS2.

Next, the supporter lifting unit 310 may elevate the supporter 300 to support the lower edges of the divided substrates SS2. Subsequently, the transport unit 500 may transport the shuttle 100 and adhesive dispensing unit 400 to fill and cure adhesive in the gap G provided between the divided substrates SS2 to form the adhesive layer AL. Here, the ultraviolet irradiation unit 420 may move with the adhesive dispensing nozzle 410 to cure the adhesive immediately after the adhesive is filled in the gap G.

Next, the transport unit 500 may move the inspection unit 430 to inspect the condition of the adhesive layer AL. Thereafter, the supporter lifting unit 310 may lower the supporter 300, and the second transport hand TH2 may unload the bonded substrate JS positioned on the stages 200.

The platform F may have a loading area A1, a working area A2, and an unloading area A3 defined therein. The loading area A1 may be a region at where the divided substrates SS2 are loaded. For example, loading of the divided substrates SS2 may occur when the shuttle 100 is in the loading area A1. The working area A2 may be a region at where bonding operations are performed. For example, adhesive dispensing may be performed on the working area A2. The unloading area A3 may be a region at where the bonded substrate JS is unloaded. For example, the bonded substrate JS may be unloaded when the shuttle 100 is in the unloading area A3.

For the sake of understanding, the boundaries between the loading area A1, the working area A2, and the unloading area A3 are shown with broken lines in the drawings, but these boundaries are merely examples.

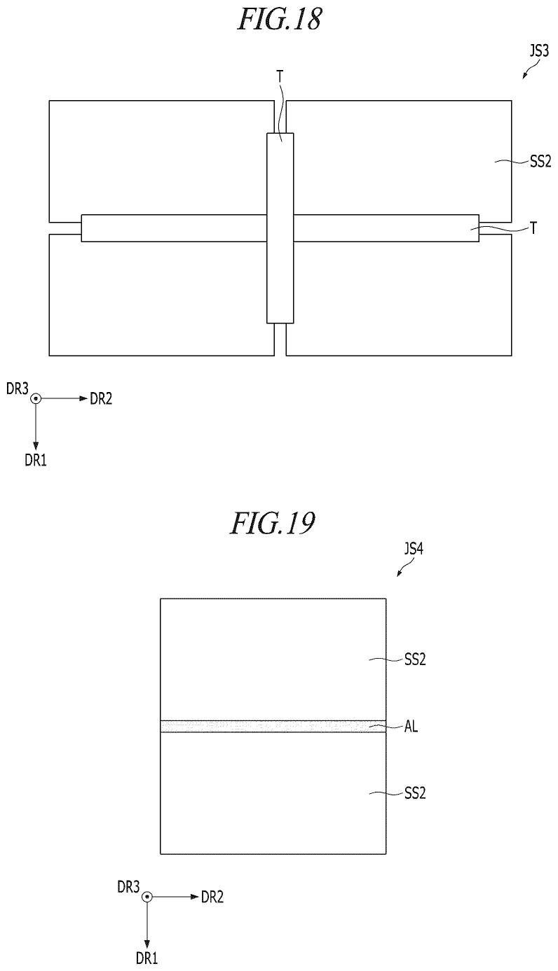

FIG. 23 illustrates a substrate loading operation in the substrate bonding apparatus shown in FIG. 21. Referring to FIG. 23, each of the stages 200 may have an upper surface 201 on which each of the divided substrates SS2 is loaded. The loading of each of the divided substrates SS2 may be performed individually by the first transport hand TH1. For example, the first transport hand TH1 may include first bars TH1-1 that are parallel to each other, and the divided substrate SS2 may be transported while seated on the first bars TH1-1. The upper surface 201 of each of the stage 200 may have grooves 202 formed therein such that the first bars TH1-1 of the first transport hand TH1 may enter and exit in a direction parallel to the upper surface 201. During the substrate loading operation, the supporter 300 may be lowered to a second position, as shown in FIG. 23, by the supporter lifting unit 310.

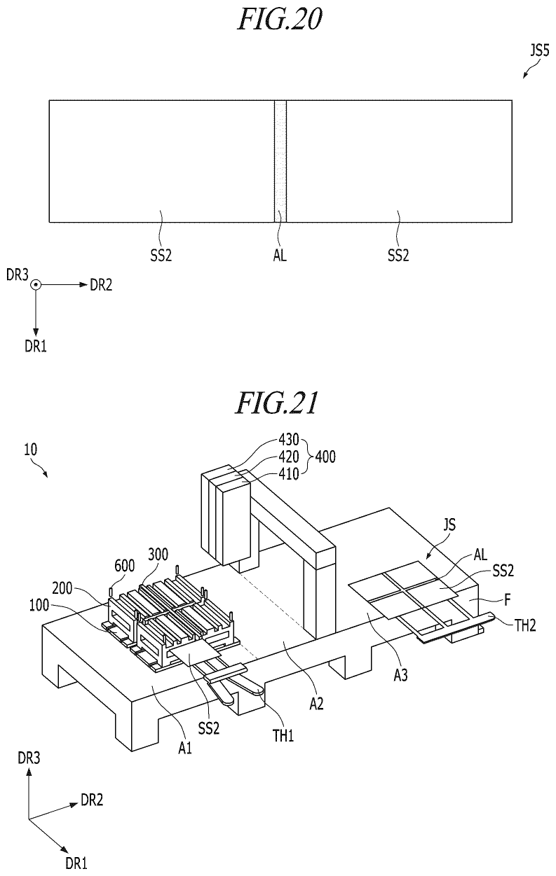

FIG. 24 illustrates a substrate bonding operation in the substrate bonding apparatus shown in FIG. 21. Referring to FIG. 24, once each of the divided substrates SS2 is loaded onto each of the stages 200 and the alignment process by the stage driving units 210 is complete, the supporter 300 may be raised to a first position, as shown in FIG. 24, by the supporter lifting unit 310. As a result, the supporter 300 may support the lower edges of the divided substrates SS2. Moreover, the supporter 300 may cover the gap G formed between the divided substrates SS2 in a planar view. Subsequently, adhesive filling and curing within the gap G may be carried out by the adhesive dispensing unit 400.

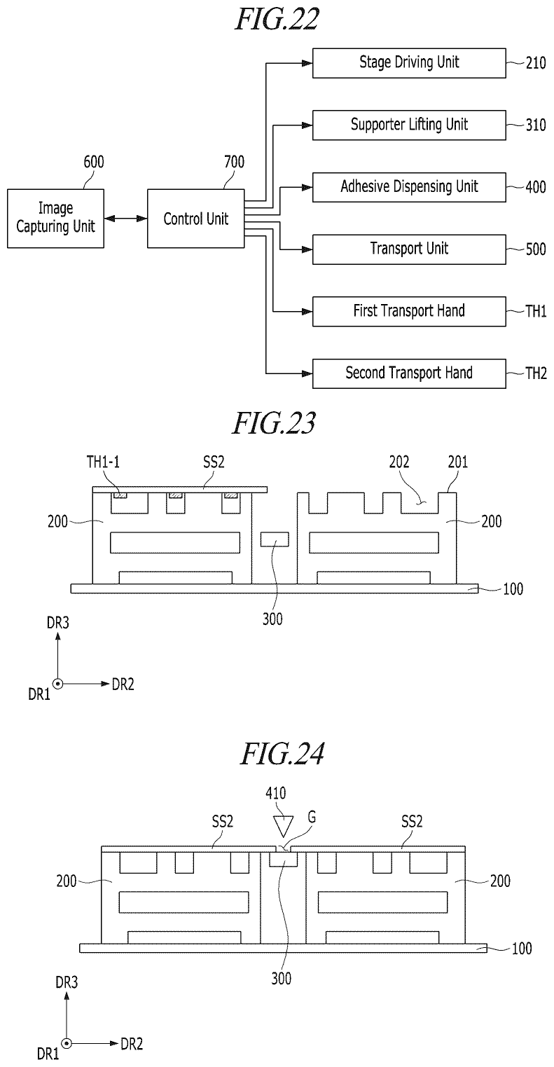

FIG. 25 illustrates a substrate unloading operation in the substrate bonding apparatus shown in FIG. 21. Referring to FIG. 25, the bonded substrate JS, which is formed by bonding the divided substrates SS2, may be unloaded by the second transport hand TH2. For example, the second transport hand TH2 may include second bars TH2-1 that are parallel to each other, and the bonded substrate JS may be transported while seated on the second bars TH2-1. Some of the second bars TH2-1 of the second transport hand TH2 may be inserted into the grooves 202 in each of the stages 200, while at least one of the second bars TH2-1 of the second transport hand TH2 may be inserted between the stages 200 to ensure more stable lifting of the bonded substrate JS. During the substrate unloading operation, the supporter 300 may have been lowered by the supporter lifting unit 310. As a result, interference between the supporter 300 and the second transport hand TH2 may be avoided.

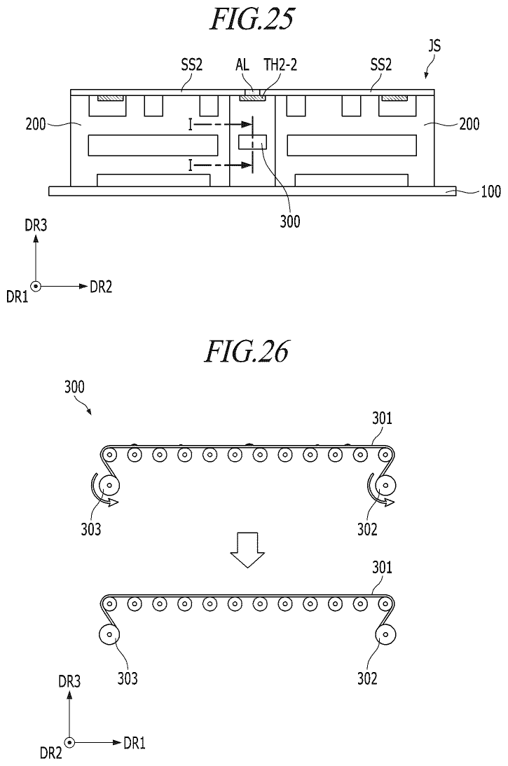

FIG. 26 is a cross-sectional view taken along the line I-I in FIG. 25, showing an example of the supporter 300. Referring to FIG. 26, the supporter 300 may include a supporter frame, a strip 301, a winder 302, and an unwinder 303. The supporter frame may be coupled to the supporter lifting unit 310 to be raised or lowered by the supporter lifting unit 310. The strip 301 may be configured to support the lower edges of the divided substrates SS2 and may cover the gap G in a planar view. The winder 302 may be configured to wind the strip 301, and the unwinder 303 may be configured to draw out the strip 301. For example, the winder 302 and the unwinder 303 may each include a roller rotatably coupled to the supporter frame and a motor for rotating the roller.

The supporter 300 may further include support rollers configured to prevent sagging of the strip 301. The winder 302 and the unwinder 303 may be configured to operate according to a preset program controlled by the control unit 700. For instance, the winder 302 and the unwinder 303 may operate after the bonding of the divided substrates SS2 is complete and the supporter 300 is lowered. As a result, the contact area of the supporter 300, that is, the area in contact with the divided substrates SS2, is switched to maintain cleanliness for subsequent bonding operations.

Additionally, the supporter 300 may further include a cleaning unit, such as a wiper, to clean the contact area of the strip 301 before the strip 301 is wound onto the winder 302.

Hereinabove, embodiments of the present disclosure have been described, but these are merely examples and are not intended to limit the present disclosure. Those skilled in the art to which the present disclosure pertains may make various modifications and changes to the embodiments by adding, changing, deleting, or adding certain elements, without departing from the scope of the technical ideas of the present disclosure as set forth in the claims and their equivalents, and such modifications and changes should also be regarded as being within the scope of the present disclosure.

What is claimed is:

1. A method for manufacturing a display device, the method comprising:
preparing divided substrates, each of the divided substrates comprising a base substrate and a circuit layer;
forming a light-emitting diode layer on the circuit layer for each of the divided substrates;
forming an encapsulation layer on the light-emitting diode layer for each of the divided substrates;
aligning the divided substrates having the encapsulation layer formed therein such that a gap is formed between adjacent ones of the divided substrates;
after the aligning of the divided substrates, bonding the divided substrates to form a single bonded substrate; and
forming a functional layer on the encapsulation layer for the bonded substrate.

2. The method of claim 1, further comprising, prior to the preparing of the divided substrates:
preparing a mother substrate comprising the base substrate;
forming the circuit layer on the base substrate of the mother substrate; and
cutting the mother substrate in which the circuit layer is formed to form the divided substrates.

3. The method of claim 2, wherein the bonded substrate has a same size as the mother substrate in a planar view.

4. The method of claim 1, wherein in the bonding of the divided substrates, the divided substrates are bonded by using adhesive tape.

5. The method of claim 1, wherein in the bonding of the divided substrates, an adhesive layer is formed in the gap to bond the divided substrates.

6. The method of claim 5, wherein in the bonding of the divided substrates, adjacent ones of the divided substrates from among the divided substrates are connected with an adhesive tape after the forming of the adhesive layer.

7. The method of claim 4, wherein the adhesive tape extends along a lengthwise direction of the gap and is attached to an upper edge of adjacent ones of the divided substrates in a widthwise direction across the gap.

8. The method of claim 7, wherein the adhesive tape is an ultraviolet-release tape configured to exhibit decreased adhesive force when irradiated with ultraviolet rays.

9. The method of claim 1, wherein the functional layer comprises a touch-sensing layer formed directly on the encapsulation layer.

10. The method of claim 1, wherein the functional layer comprises a color filter layer formed directly on the encapsulation layer.

11. The method of claim 1, further comprising removing a bonded portion from the bonded substrate in which the functional layer has been formed to form redivided substrates.

12. The method of claim 11, wherein each of the redivided substrates has cell areas and a peripheral area defined therein, and
wherein the method further comprises cutting each of the redivided substrates to separate the cell areas.

13. A substrate bonding apparatus comprising:
a shuttle;
stages arranged on the shuttle, each of the stages having an upper surface on which divided substrates are respectively mounted;
stage driving units coupled to the shuttle and configured to transport and rotate each of the stages;
an adhesive dispensing unit configured to fill an adhesive in a gap between adjacent ones of the divided substrates; and
a transport unit configured to transport the shuttle or the adhesive dispensing unit.

14. The substrate bonding apparatus of claim 13, wherein the adhesive dispensing unit comprises:
an adhesive dispensing nozzle; and
an ultraviolet irradiation unit configured to irradiate ultraviolet rays onto the adhesive in the gap.

15. The substrate bonding apparatus of claim 14, wherein the adhesive dispensing unit further comprises an inspection unit configured to examine a condition of an adhesive layer in the gap.

16. The substrate bonding apparatus of claim 13, further comprising:
an image capturing unit configured to generate captured images of the divided substrates mounted on the stages; and
a control unit configured to control the stage driving units based on the captured images such that the gap has a constant size between the divided substrates.

17. The substrate bonding apparatus of claim 13, further comprising a supporter between the stages to support lower edges of the divided substrates mounted on the stages and to cover the gap in a planar view.

18. The substrate bonding apparatus of claim 17, wherein the supporter comprises:
a strip supporting the lower edges of the divided substrates and covering the gap in a planar view;
an unwinder configured to draw out the strip; and
a winder configured to wind the strip.

19. The substrate bonding apparatus of claim 17, further comprising a supporter lifting unit configured to transport the supporter to a first position and a second position, the supporter supporting the lower edges of the divided substrates in the first position, the second position being lower than the first position.

20. The substrate bonding apparatus of claim 19, further comprising:
a first transport hand configured to load the divided substrates onto the stages, respectively; and
a second transport hand configured to unload a bonded substrate formed by bonding the divided substrates together from the stages,
wherein each of the stages has grooves in the upper surface thereof to allow the first transport hand and the second transport hand to enter and exit in a direction parallel to the upper surface.
